(19) United States
(12) Patent Application Publication
(10) Pub. No.: US 2009/0133237 A1
(43) Pub. Date: May 28, 2009

(54) PIEZOELECTRIC DEVICE AND METHOD OF MANUFACTURING PIEZOELECTRIC RESONATORS

(76) Inventors: Keiji ONISHI, Osaka (JP); Hiroshi Nakatsuka, Osaka (JP); Takehiko Yamakawa, Osaka (JP); Tomohiro Iwasaki, Osaka (JP); Tomohide Kamiyama, Osaka (JP)

Correspondence Address: WENDEROTH, LIND & PONACK L.L.P., 1030 15th Street, N.W., Suite 400 East, Washington, DC, 20005-1503, US

(21) Appl. No.: 12/338,189

(22) Filed: Dec. 18, 2008

Related U.S. Application Data
(62) Division of application No. 11/511,424, filed on Aug. 29, 2006.

(30) Foreign Application Priority Data
Aug. 30, 2005 (JP) 2005-248648

(51) Int. Cl. H01L 41/24

(52) U.S. Cl. 29/25.35

(57) ABSTRACT

A piezoelectric resonator comprises a piezoelectric material layer 101, a first electrode 102 formed on one major surface of the piezoelectric material layer 101, and having a cross-section in the shape of a trapezoid whose longer side contacts the piezoelectric material layer 101, and a second electrode 103 formed on the other major surface of the piezoelectric material layer 101, and having a cross-section in the shape of a trapezoid whose longer side contacts the piezoelectric material layer 101.

### BACKGROUND OF THE INVENTION

1. Field of the Invention

The present invention relates to a piezoelectric resonator employing a piezoelectric thin film for use in radio communication apparatuses, such as mobile telephones, wireless LAN apparatuses, and the like, and a method for manufacturing the piezoelectric resonator.

2. Description of the Background Art

There is a demand for parts having a smaller size and a lighter weight while keeping a high performance which are incorporated in mobile communication apparatuses and the like. For example, a small size and low insertion loss are required for filters and duplexers which are used in mobile telephones and select a radio frequency signal. As one of the filters satisfying the requirement, a filter is known which employs a piezoelectric resonator which utilizes a piezoelectric thin film.

FIG. 12 is a cross-sectional view of a conventional piezoelectric resonator (see Japanese National Phase PCT Laid-Open Publication No. 2002-509644). The conventional piezoelectric resonator is manufactured by the following procedure.

Initially, a convex portion which is to be a cavity 506 is formed on a surface of a substrate 504 made of silicon or the like. Thereafter, the convex portion is filled with a sacrifice layer made of a soluble material, such as phosphosilicate glass (PSG), an organic resist, or the like, before planarization. Next, an insulating film 510 made of silicon oxide (SiO₂), silicon nitride (Si₃N₄) or the like is formed on the sacrifice layer. Next, a conductive film which is to be a first electrode 502 is formed on the insulating film 510. Next, the conductive film is shaped into a predetermined shape by patterning using a typical photolithography technique to form the first electrode 502. Here, the first electrode 502 is formed by sputtering or vapor deposition, and is commonly made of molybdenum (Mo), tungsten (W), aluminum (Al), or the like. Next, a piezoelectric material layer 501 made of a piezoelectric material, such as aluminum nitride (AlN), zinc oxide (ZnO) or the like, is formed on the first electrode 502. A conductive film which is to be a second electrode 503 is formed on the piezoelectric material layer 501. Next, the second electrode 503 is formed by etching the conductive film again. Finally, the sacrifice layer is removed by etching using a solvent, such as hydrofluoric acid, an organic solvent or the like, to form the cavity 506.

As can be seen from FIG. 12, when each electrode is formed by wet etching, the first electrode 502 has a cross-section in the shape of a trapezoid whose shorter side (opposite to the base) contacts the piezoelectric material layer 501, and the second electrode 503 has a cross-section in the shape of a trapezoid whose longer side (the base) contacts the piezoelectric material layer 501. Note that, when a technique, such as dry etching or the like, is used, the first electrode 502 and the second electrode 503 both have a rectangular shape which has a perpendicular end surface.

FIG. 13 is a cross-sectional view of another conventional piezoelectric resonator (see Japanese Patent Laid-Open Publication No. 2002-251190). This conventional piezoelectric resonator has a structure different from that of the above-described conventional piezoelectric resonator in that the cavity 506 is replaced with an acoustic mirror layer 607 in which low acoustic impedance layers 605 and high acoustic impedance layers 606 are alternately stacked. This conventional piezoelectric resonator is also manufactured by successive lamination from a substrate 604. Therefore, when each electrode is formed by wet etching, a first electrode 602 has a cross-section in the shape of a trapezoid whose shorter side (opposite to the base) contacts a piezoelectric material layer 601, and a second electrode 603 has a cross-section in the shape of a trapezoid whose longer side (the base) contacts the piezoelectric material layer 601.

However, in the case of the above-described conventional piezoelectric resonator, since the piezoelectric material layer and the second electrode are formed after the formation of the first electrode, the first electrode has a cross-section in the shape of a trapezoid whose shorter side (opposite to the base) contacts the piezoelectric material layer or a rectangular having a perpendicular end surface. Therefore, the piezoelectric resonator has a problem that an unwanted spurious signal occurs in electrical characteristics thereof, or the like.

Also, the conventional piezoelectric resonator is manufactured using the procedure in which the piezoelectric material layer is formed on the first electrode. Therefore, the piezoelectric resonator has a problem that the crystallinity of the piezoelectric material layer is deteriorated at an end portion of the first electrode, so that a Q value which is the sharpness of resonance is deteriorated.

Also, the conventional piezoelectric resonator is manufactured using the procedure in which the piezoelectric material layer is formed on the sacrifice layer or the acoustic mirror layer. Therefore, the piezoelectric resonator has a problem that the flatness of a surface on which the piezoelectric material layer is formed is impaired, so that the crystallinity of the piezoelectric material layer is deteriorated.

### SUMMARY OF THE INVENTION

Therefore, an object of the present invention is to a piezoelectric resonator having satisfactory characteristics without an unwanted spurious signal, and a method for manufacturing the piezoelectric resonator.

The present invention is directed to a piezoelectric resonator which vibrates at a predetermined frequency. To achieve the above-described object, the piezoelectric resonator of the present invention comprises a piezoelectric material layer made of a piezoelectric thin film, a first electrode formed on one major surface of the piezoelectric material layer, and having a cross-section in the shape of a trapezoid whose longer side contacts the piezoelectric material layer, and a second electrode formed on the other major surface of the piezoelectric material layer, and having a cross-section in the shape of a trapezoid whose longer side contacts the piezoelectric material layer.

Preferably, the cross-sectional shape of the first electrode and the cross-sectional shape of the second electrode are symmetric about the piezoelectric material layer. The piezoelectric material layer is fixed to a substrate via a support portion made of an inorganic material or a thin film layer made of an inorganic material.

The piezoelectric resonator of the above-described configuration is manufactured by the steps of forming a piezoelectric material layer on a first substrate, forming a first electrode on one major surface of the piezoelectric material layer, the first electrode having a cross-section in the shape of a trapezoid whose longer side contacts the piezoelectric material layer, transferring the piezoelectric material layer on which the first electrode is formed, from the first substrate to a second substrate using an attachment method via a support portion, and forming a second electrode on the other major surface of the piezoelectric material layer, the second electrode having a cross-section in the shape of a trapezoid whose longer side contacts the piezoelectric material layer.

The transferring step may include attaching the first and second substrates via a melted state or a half-melted state of the support portion made of a metal, or by surface-activating and superposing the support portion made of an oxide thin film layer and the second substrate.

Although the piezoelectric resonator of the present invention functions alone, a radio frequency part, such as a filter, a duplexer, or the like can be achieved by connecting two or more piezoelectric resonator of the present invention. The radio frequency part can be used in a communication apparatus along with an antenna, a transmission circuit, a reception circuit, and the like.

According to the present invention, an unwanted spurious signal can be effectively suppressed, thereby making it possible to achieve a piezoelectric resonator having a high Q value. Particularly, according to the piezoelectric resonator manufacturing method of the present invention, a high-quality piezoelectric material layer can be applied to a resonator without impairing the crystallinity of the piezoelectric material layer.

These and other objects, features, aspects and advantages of the present invention will become more apparent from the following detailed description of the present invention when taken in conjunction with the accompanying drawings.

### BRIEF DESCRIPTION OF THE DRAWINGS

FIGS. 1A to 1C are diagrams schematically illustrating a structure of a piezoelectric resonator according to a first embodiment of the present invention;

FIGS. 2A and 2B are diagram roughly illustrating a procedure of a piezoelectric resonator manufacturing method according to the first embodiment;

FIG. 3 is a diagram illustrating an electrical characteristic (admittance) of the piezoelectric resonator of the first embodiment;

FIGS. 4A and 4B are cross-sectional views of structures of piezoelectric resonators of the conventional art and the present invention for describing the electrical characteristics of FIG. 3;

FIGS. 5A to 5C are diagrams schematically illustrating another structure of the piezoelectric resonator of the first embodiment of the present invention;

FIGS. 6A and 6B are diagrams schematically illustrating a structure of a piezoelectric resonator according to a second embodiment of the present invention;

FIGS. 7A and 7B are diagrams roughly illustrating a procedure of a piezoelectric resonator manufacturing method of the second embodiment;

FIGS. 8 and 9 are diagrams illustrating piezoelectric filter circuits employing the piezoelectric resonator of the present invention;

FIG. 10 is a diagram illustrating an exemplary duplexer which employs the piezoelectric resonator of the present invention;

FIG. 11 is a diagram illustrating an exemplary communication apparatus employing the piezoelectric resonator of the present invention; and

FIGS. 12 and 13 are diagrams schematically illustrating a structure of a conventional piezoelectric resonator.

### DESCRIPTION OF THE PREFERRED EMBODIMENTS

Hereinafter, embodiments of the present invention will be described with reference to the accompanying drawings.

### First Embodiment

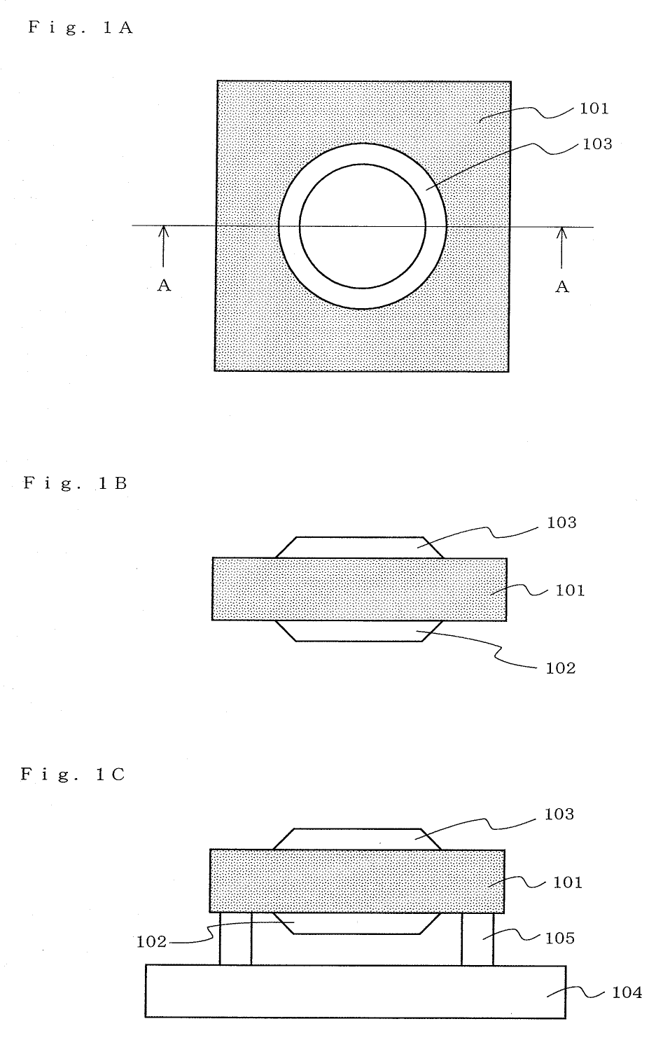

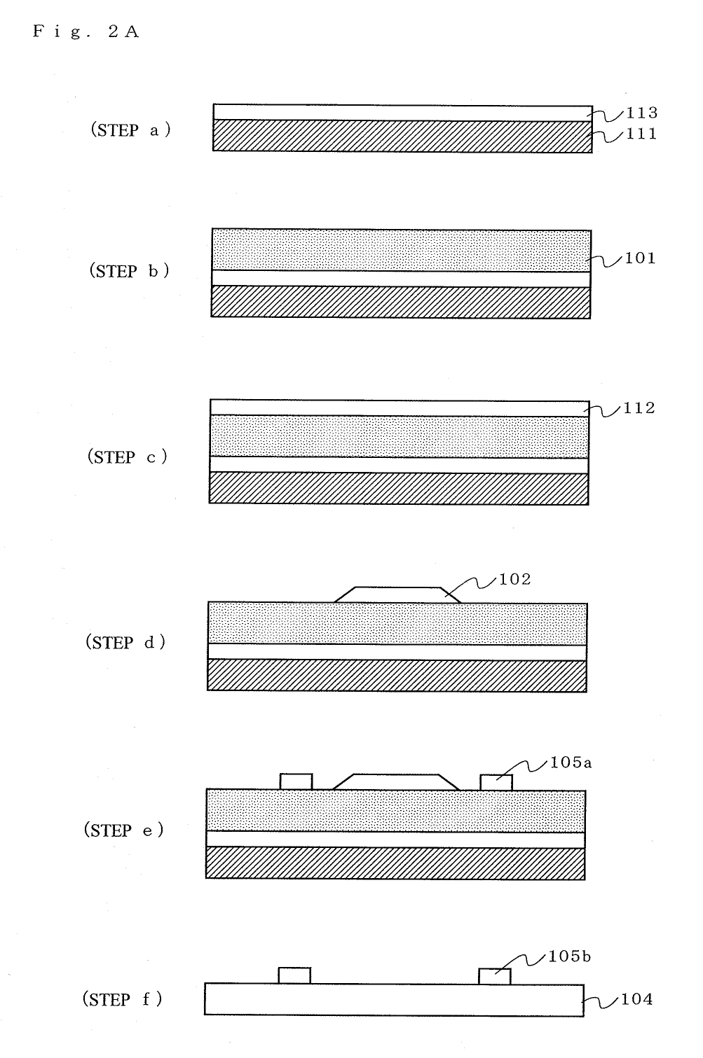

FIG. 1A is a top plan view schematically illustrating a structure of a piezoelectric resonator according to a first embodiment of the present invention. FIGS. 1B and 1C are cross-sectional views of the piezoelectric resonator, taken along line A-A of FIG. 1A. FIG. 1B illustrates only a vibration portion. FIG. 1C illustrates that the vibration portion is placed on a substrate 104 via a support portion 105.

The vibration portion is composed of a piezoelectric material layer 101, and a first electrode 102 and a second electrode 103 which are formed to sandwich the piezoelectric material layer 101. The piezoelectric material layer 101 is made of a piezoelectric material, such as aluminum nitride (AlN), zinc oxide (ZnO), a lead zirconate titanate (PZT)-based material, lithium niobate (LiNbO₃), lithium tantalate (LiTaO₃), potassium niobate (KNbO₃), or the like. The first electrode 102 and the second electrode 103 are made of a conductive material, such as molybdenum (Mo), aluminum (Al), tungsten (W), platinum (Pt), gold (Au), titanium (Ti), copper (Cu), or the like, or a laminated metal or an alloy thereof.

As illustrated in FIGS. 1B and 1C, in the piezoelectric resonator of the first embodiment, the first electrode 102 is formed on one major surface of the piezoelectric material layer 101, and has a cross-section in the shape of a trapezoid whose longer side (the base) contacts the piezoelectric material layer 101. The second electrode 103 is formed on the other major surface of the piezoelectric material layer 101, and has a cross-section in the shape of a trapezoid whose longer side (the base) contacts the piezoelectric material layer 101. Although the first electrode 102 and the second electrode 103 have line symmetry in this example, a relationship (in terms of thickness, position, etc.) between the first electrode 102 and the second electrode 103 is not particularly limited. Also, the shape of the piezoelectric material layer 101 is not limited.

When the piezoelectric resonator is made of a piezoelectric thin film, a vibration portion thereof is considerably thin (e.g., about several micrometers in the case of a 2-GHz band resonator). Therefore, generally, as illustrated in FIG. 1C, the piezoelectric resonator is used while the vibration portion is placed on the substrate. In the example of FIG. 1C, the vibration portion is fixed via the support portion 105 to the substrate 104. The substrate 104 is made of a material, such as silicon (Si), glass, sapphire, or the like. The support portion 105 is made of materials including a gold-tin (AuSn) alloy as a major component since a characteristic piezoelectric resonator manufacturing method (described below) is employed.

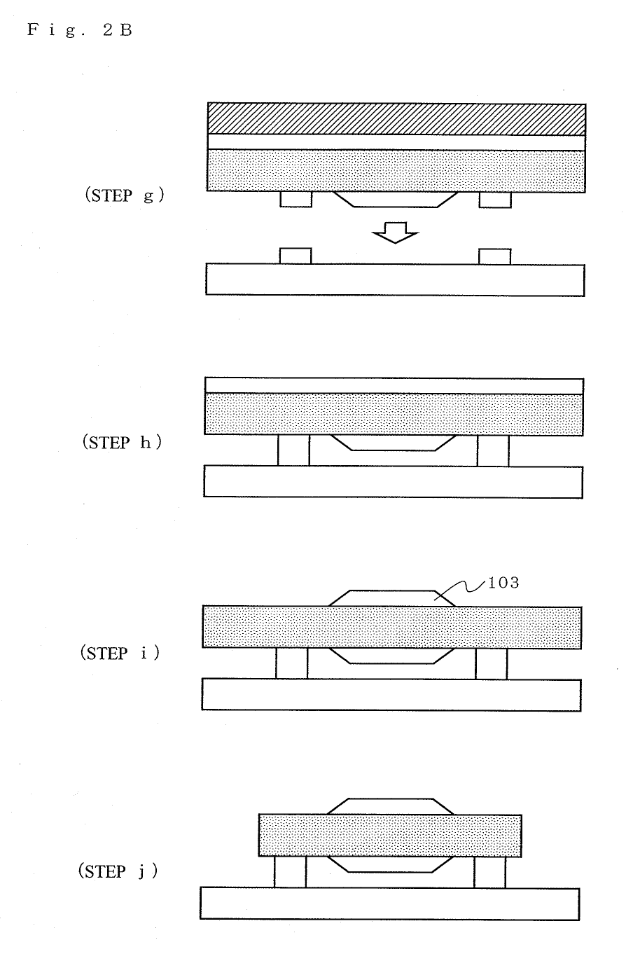

FIGS. 2A and 2B are diagram roughly illustrating a procedure of a piezoelectric resonator manufacturing method according to the first embodiment. In this manufacturing method, the piezoelectric resonator of FIGS. 1A to 1C is manufactured by a wafer-to-wafer bonding method.

Initially, a film formation substrate 111 made of silicon, glass, sapphire or the like is prepared. An electrode film 113 which is to be the second electrode 103 is formed on the film formation substrate 111 (step a in FIG. 2A). Note that a flat thermal oxide film (not shown) is previously is formed as an insulating film on the film formation substrate 111. Next, the piezoelectric material layer 101 is formed on the electrode film 113 (step b in FIG. 2A). For example, when a 2-GHz band piezoelectric resonator is formed, the piezoelectric material layer 101 has a thickness of about 1100 nm, and the electrode film 113 has a thickness of about 300 nm. In this example, the piezoelectric material layer 101 is formed on the flat film formation substrate 111 via the electrode film 113. Therefore, there is not an influence, such as occurrence of a discontinuous portion of the electrode film 113, a surface deterioration of the electrode film 113 occurring during patterning, or the like, so that the piezoelectric material layer 101 having satisfactory crystallinity can be obtained.

Next, an electrode film 112 which is to be the first electrode 102 is formed on the piezoelectric material layer 101 (step c in FIG. 2A). Thereafter, the electrode film 112 is shaped into a predetermined trapezoidal shape by patterning using a typical photolithography technique to form the first electrode 102 (step d in FIG. 2A). In this example, the first electrode 102 is formed by dissolving and removing an unwanted portion of the electrode film 112 using a wet etching technique with a nitric acid-based enchant (nitric acid-sulfuric acid-water). Thereby, the first electrode 102 can be formed so as to have a cross-section in a taper shape. Specifically, an electrode in the shape of a trapezoid whose longer side (the base) contacts the piezoelectric material layer 101, can be obtained. Note that, as long as a similar trapezoidal shape is obtained, the present invention is not limited to the nitric acid-based enchant, and a technique, such as dry etching or the like, may be employed.

Next, a multilayer film 105a which is to be a portion of the support portion 105 is formed on the piezoelectric material layer 101 by electron beam deposition, sputtering, or the like (step e in FIG. 2A). In this example, a portion of the support portion 105 is formed by patterning using a lift-off technique (Ti/Au/AuSn are deposited in this order by electron beam deposition). The pattern is preferably formed in a region other than the first electrode 102 which does not inhibit piezoelectric vibration. Thus, preparation of the film formation substrate 111 is completed.

Next, the substrate 104 for supporting the vibration portion is prepared. A multilayer film 105b which is to be a portion of the support portion 105 is formed on the substrate 104 by electron beam deposition, sputtering, or the like (step f in FIG. 2A). Note that a flat thermal oxide film or the like (not shown) is previously formed as an insulating film on the substrate 104. In this example, the support portion 105 is formed by patterning using a lift-off technique (Ti/Au/AuSn are deposited in this order by electron beam deposition) so that the AuSn alloy layers contact each other when the substrate 104 is caused to face the film formation substrate 111. Note that the pattern of the support portion 105 formed on the substrate 104 does not need to completely match the pattern of the support portion 105 formed on the film formation substrate 111, and a margin may be preferably provided, taking the positioning accuracy of both the substrates into consideration.

Next, the support portion 105 (the multilayer film 105a) of the film formation substrate 111 and the support portion 105 (the multilayer film 105b) of the substrate 104 are caused to face each other, so that both the support portions 105 are bonded together by eutectic crystallization of gold and tin (step g in FIG. 2B). In this case, pressure may be applied to both the substrates. In this example, the substrates are attached together by applying a press pressure of 3 atmospheric pressure. Also, the bonded substrates may be heated so that AuSn in the contacting portions thereof is melted, and thereafter, the temperature is reduced, thereby making it possible to obtain a firm metal bond. Thereby, a piezoelectric resonator having an excellent level of junction reliability can be obtained.

Although an AuSn alloy is used for the support portion 105 in this example, the present invention is not limited to this. For example, when the two substrates are bonded together via a half-melted state or a melted state of the support portions 105, the melting point (solidus temperature) may be higher than a solder reflow temperature when the piezoelectric resonator is mounted on a mother board, and lower than the melting point of the electrode material or the like of the piezoelectric resonator. Alternatively, the support portions 105 may be bonded together by diffused junction in which metals are mutually diffused at the melting point or less, or by surface activation of contact surfaces by a plasma treatment or the like at room temperature. When junction is performed at room temperature, a residual thermal stress can be removed from the vibration portion, thereby making it possible to obtain a piezoelectric resonator which has a high manufacturing yield, and a less change over time, such as frequency variation or the like.

Next, the film formation substrate 111 is removed from a product of the two substrates bonded together (step h in FIG. 2B). For example, the film formation substrate 111 can be removed by dry etching. By steps g and h, the product originally present on the film formation substrate 111 is transferred onto the substrate 104. Next, the electrode film 113 is shaped into a predetermined trapezoidal shape by patterning using a typical photolithography technique to form the second electrode 103 (step i in FIG. 2B). Thereby, the second electrode 103 having a cross-section in the shape of a trapezoid whose longer side (the base) contacts the piezoelectric material layer 101, is formed. Finally, an unnecessary portion is removed from the piezoelectric material layer 101 by etching (step j in FIG. 2B), thereby completing the piezoelectric resonator of FIG. 1C.

Although the film formation substrate 111 is removed by etching in the above-described manufacturing method, a release layer may be provided between the electrode film 113 and the film formation substrate 111, and the film formation substrate 111 may be released with the release layer. Alternatively, the electrode film 113 may not be formed, and a release layer and the piezoelectric material layer 101 may be stacked on the film formation substrate 111. In this case, after the film formation substrate 111 is released, the second electrode 103 needs to be formed by patterning. If gallium nitride (GaN), which has optical characteristics as those of AlN, is used as the release layer, AlN can be transferred by decomposing only GaN by laser irradiation. Alternatively, as the release layer, a metal film having less affinity to the electrode film 113, a metal film or an oxide which is easily dissolved in a solvent or the like, glass, or the like may be used.

Next, an effect of the piezoelectric resonator of the first embodiment due to the structure formed by the above-described manufacturing method, will be described.

In the conventional piezoelectric resonator, the first electrode needs to be subjected to patterning before the piezoelectric material layer is formed. However, in the present invention, the film formation substrate 111 is prepared, and the piezoelectric material layer 101 is formed on the electrode film 113 before patterning. Therefore, there is not an influence, such as occurrence of a discontinuous portion of the electrode film 113, a surface deterioration of the electrode film 113 occurring during patterning, or the like, so that the piezoelectric material layer 101 having satisfactory crystallinity can be obtained. Specifically, the piezoelectric material layer (AlN) formed after subjecting the electrode film (Mo) to patterning has a (0002)-plane X diffraction Full Width Half Maximum (FWHM) of 1.5 degrees, which is an index of crystallinity, while the piezoelectric material layer (AlN) formed without subjecting the electrode film (Mo) to patterning has an FWHM of 1.1 degrees.

Thus, in the present invention, the first electrode 102 is subjected to patterning after the piezoelectric material layer 101 is formed, thereby making it possible to significantly improve the crystallinity of the piezoelectric material layer 101. Thereby, it is also possible to improve the Q value which indicates a performance of the piezoelectric resonator. According to experiments conducted by the present inventors, it was found that the Q value is improved by about 20%. Such a Q value improving effect is exhibited even if any electrode material, any piezoelectric material, and any substrate material are used. In addition, the improvement of the crystallinity leads to an improvement in dielectric strength of the piezoelectric material layer and an improvement in power handling capability of the piezoelectric resonator.

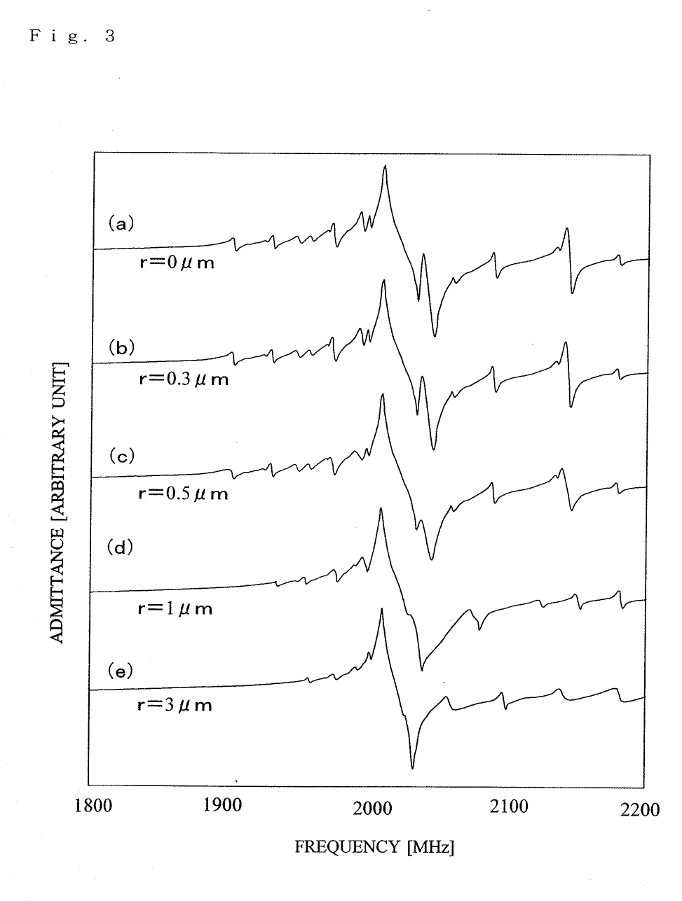

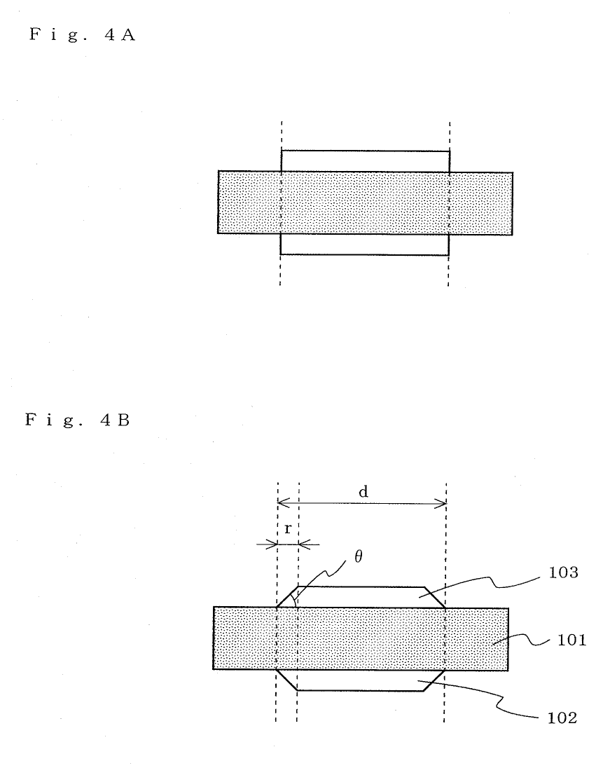

FIG. 3 is a diagram illustrating an electrical characteristic (admittance) of the piezoelectric resonator of the first embodiment. FIGS. 4A and 4B are cross-sectional views of structures of piezoelectric resonators for describing the electrical characteristics of FIG. 3.

In FIG. 3, (a) indicates characteristics of a conventional piezoelectric resonator (FIG. 4A), indicating that a spurious signal (unwanted electrical signal) occurs between a resonant frequency and an anti-resonant frequency due to unwanted vibration. In (a) of FIG. 3, as illustrated in FIG. 4A, it is considered that the presence of an electrode forms a discontinuous acoustic portion at a portion indicated by a dashed line, so that reflection (e.g., unwanted mode vibration, etc.) occurs, propagating in a direction (lateral direction) perpendicular to a vibration direction, resulting in occurrence of a spurious signal.

In FIG. 3, (b) to (e) indicate characteristics of the piezoelectric resonator of the first embodiment. Here, the longer side (the base) d of each of the first electrode 102 and the second electrode 103 which sandwich the piezoelectric material layer 101 and have a trapezoidal shape (in this example, each electrode has a circular shape, and its diameter corresponds to d) is 50 μm, while r is 0.3 μm in (b) of FIG. 3, 0.5 μm in (c) of FIG. 3, 1 μm in (d) of FIG. 3, and 3 μm in (e) of FIG. 3. As can be seen from FIG. 3, in the piezoelectric resonator of the present invention, the spurious signal is suppressed more than in the conventional piezoelectric resonator. By setting the value of r so that the thickness at the end portion of the electrode is gradually changed, unwanted mode vibration can be suppressed from being reflected at the end portion of the electrode, so that a spurious signal can be reduced in the admittance characteristics. The spurious signal suppressing effect is obtained if the value of r is larger than or equal to the thickness of the electrode, though the value of r is not particularly limited. More preferably, if a taper angle θ is 30° or less (r=0.5 μm or more in the example of FIG. 3), the spurious signal suppressing effect is obtained. Thereby, it is possible to achieve a piezoelectric resonator which has a high Q value without a spurious signal from the vicinity of a resonant frequency to the vicinity of an anti-resonant frequency.

As described above, according to the piezoelectric resonator of the first embodiment of the present invention, an unwanted spurious signal is effectively suppressed, thereby making it possible to achieve a piezoelectric resonator having a high Q value. Particularly, by using the piezoelectric resonator manufacturing method of the present invention, a high-quality piezoelectric material layer can be applied to a resonator without impairing the crystallinity of the piezoelectric material layer.

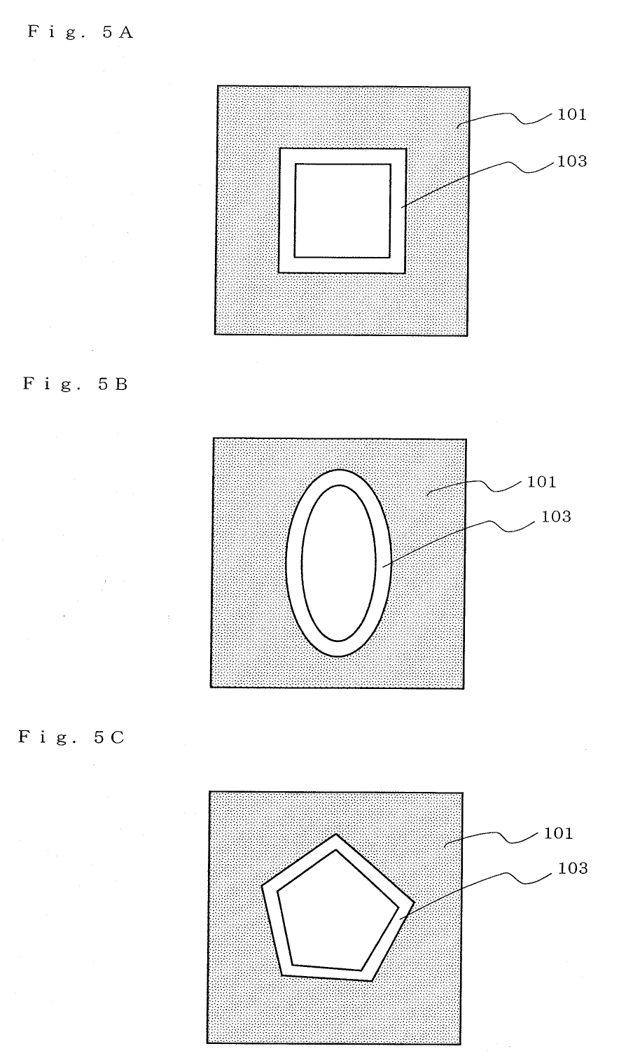

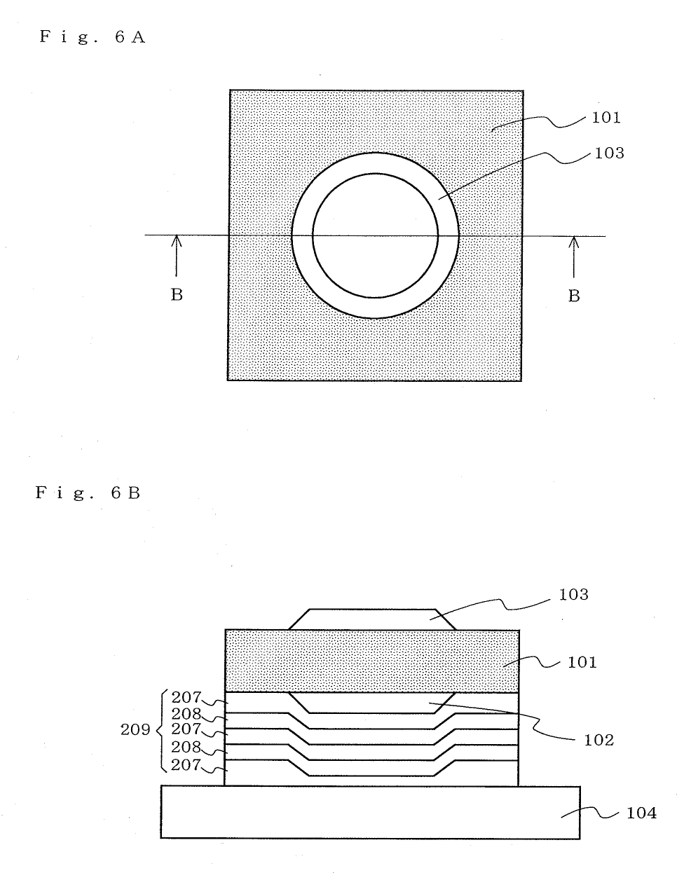

Note that it has been described in the first embodiment that, regarding the shape of the piezoelectric resonator, the first electrode 102 and the second electrode 103 are in the shape of a circle. However, the first electrode 102 and the second electrode 103 can have various shapes, such as a rectangular shape, an elliptical shape, a polygonal shape, and the like, as illustrated in FIGS. 5A to 5C.

In addition, in the structure of the piezoelectric resonator of the first embodiment, an oxide film, a nitride film, or an organic film may be provided at any positions for the purposes of insulation, temperature compensation, a deterioration in characteristics due to foreign matter, an improvement in resistance to humidity, and the like.

### Second Embodiment

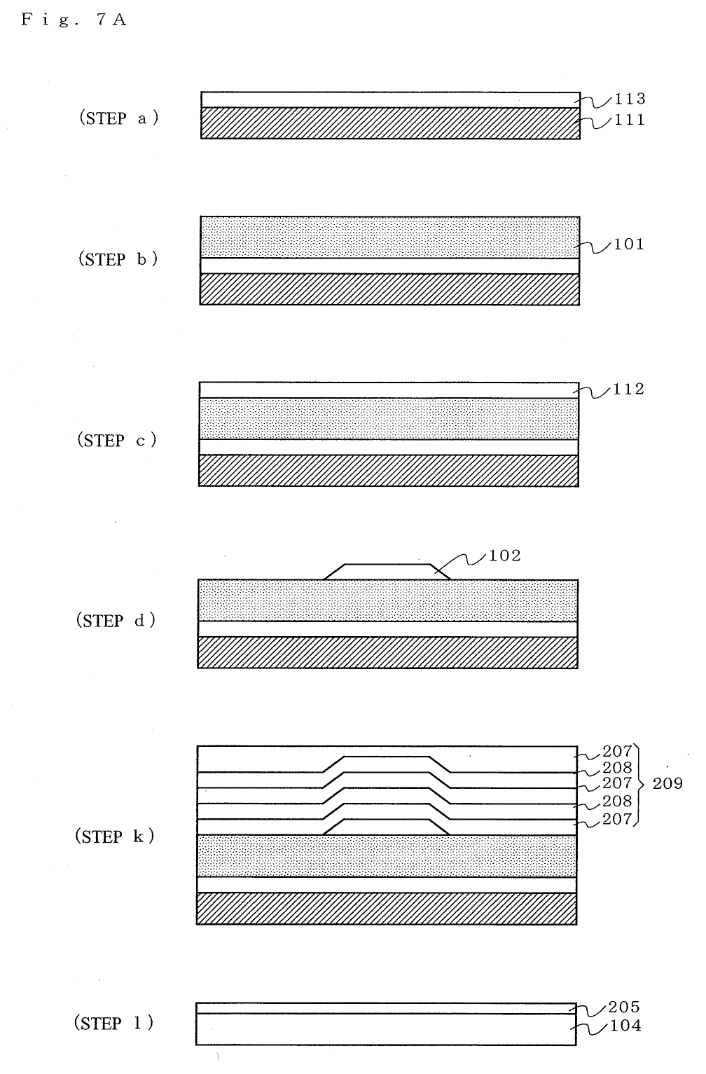

FIG. 6A is a top plan view schematically illustrating a structure of a piezoelectric resonator according to a second embodiment of the present invention. FIG. 6B is a cross-sectional view of the piezoelectric resonator, taken along line B-B of FIG. 6A. The piezoelectric resonator of the second embodiment is different from the piezoelectric resonator of the first embodiment in that the cavity formed by the support portion 105 is replaced with an acoustic mirror layer 209. Therefore, in the second embodiment, the same parts as those of the first embodiment, except for the acoustic mirror layer 209, are indicated by the same reference numerals and a portion thereof will not be described.

As illustrated in FIG. 6B, in the piezoelectric resonator of the second embodiment, the first electrode 102 is shaped into a trapezoidal shape whose longer side (the base) contacts the piezoelectric material layer 101. The second electrode 103 is shaped into a trapezoidal shape whose longer side (the base) contacts the piezoelectric material layer 101.

The acoustic mirror layer 209 is composed of low acoustic impedance layers 207 made of silicon oxide or the like and high acoustic impedance layers 208 made of hafnium oxide or the like, which are alternately stacked. In this example, a five-layer structure is provided, though the number of layers is not limited. The low acoustic impedance layers 207 and the high acoustic impedance layers 208 are stacked and formed on the first electrode 102, so that the low acoustic impedance layers 207 and the high acoustic impedance layers 208 are bent to fit the trapezoidal shape of the first electrode 102 as illustrated in FIG. 6B. Preferably, by setting a thickness of each of the low acoustic impedance layers 207 and the high acoustic impedance layers 208 to be ¼ of an acoustic wavelength, elastic waves excited by the vibration portion can be effectively confined.

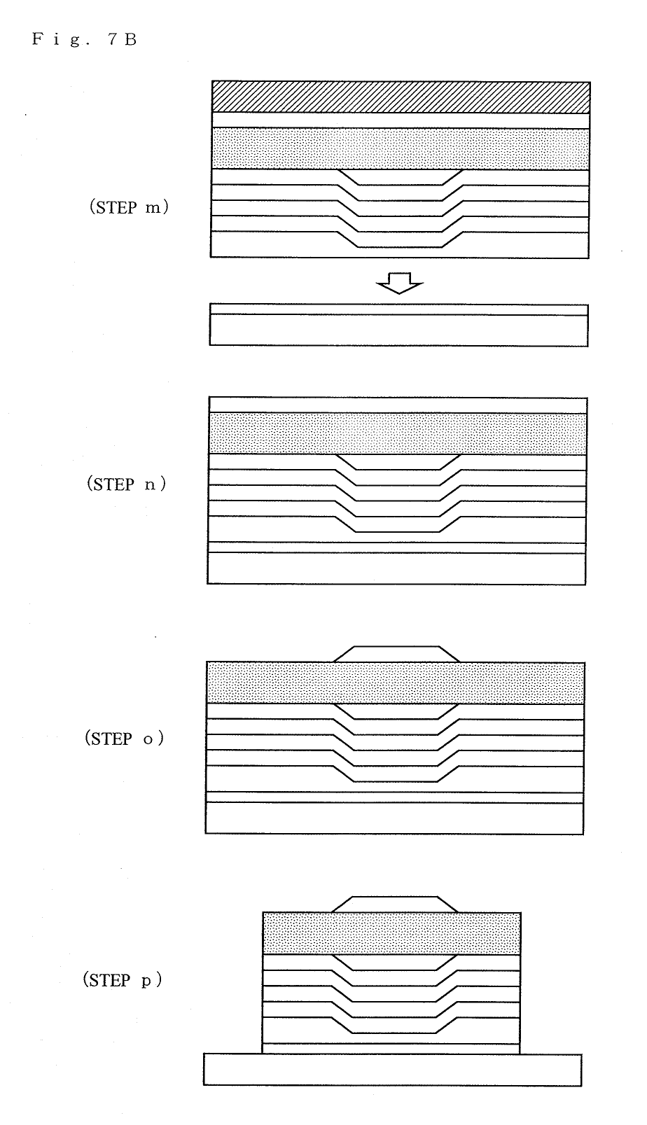

FIGS. 7A and 7B are diagrams roughly illustrating a procedure of a piezoelectric resonator manufacturing method of the second embodiment. Also in this manufacturing method, by using a wafer-to-wafer bonding method as in the first embodiment, the piezoelectric resonator of FIGS. 6A and 6B is manufactured. Note that, in the piezoelectric resonator manufacturing method of the second embodiment, steps a to d are similar to those of the piezoelectric resonator manufacturing method of the first embodiment and will not be described.

After the end of step d of FIG. 7A, the acoustic mirror layer 209 is formed on the piezoelectric material layer 101 and the first electrode 102 (step k in FIG. 7A). For example, silicon oxide (low acoustic impedance layer 207) is formed by Chemical Vapor Deposition (CVD), and hafnium oxide (high acoustic impedance layer 208) is formed by Physical Vapor Deposition (PVD).

Next, the substrate 104 for supporting a vibration portion is prepared, and a junction layer 205 (corresponding to the support portion 105) made of Ti/Au/AuSn alloy is formed by electron beam deposition, sputtering, or the like (step 1 in FIG. 7A). Note that a flat thermal oxide film or the like (not shown) is previously formed as an insulating film on the substrate 104.

Next, the acoustic mirror layer 209 of the film formation substrate 111 and the junction layer 205 of the substrate 104 are caused to face each other, and are bonded together by eutectic crystallization of gold and tin (step m of FIG. 7B). In this case, pressure may be applied to both the substrates. Also, the attached substrates may be heated so that AuSn in the contacting portions thereof is melted, and thereafter, the temperature is reduced, thereby making it possible to obtain a firm metal bond.

Although the AuSn alloy is used for the junction layer 205 in this example, the present invention is not limited to this. For example, when the two substrates are bonded together via a half-melted state or a melted state of the junction layer 205, the melting point (solidus temperature) may be higher than a solder reflow temperature when the piezoelectric resonator is mounted on a mother board, and lower than the melting point of the electrode material or the like of the piezoelectric resonator. Alternatively, when the acoustic mirror layer 209 is made of a metal, such as molybdenum, tungsten, or the like, the substrates may be attached together by diffused junction in which metals are mutually diffused at the melting point or less. Alternatively, when the lowermost layer of the acoustic mirror layer 209 is an oxide layer or the like, the substrates may be attached together by surface activation of contact surfaces by a plasma treatment or the like at room temperature. In this case, the junction layer does not need to be particularly formed on the substrate 104, and the piezoelectric resonator and the substrate can be directly joined together.

Next, the film formation substrate 111 is removed from a product of the two substrates bonded together (step n in FIG. 7B). Next, the electrode film 113 is shaped into a predetermined trapezoidal shape by patterning using a typical photolithography technique to form the second electrode 103 (step o in FIG. 7B). Thereby, the second electrode 103 having a cross-section in the shape of a trapezoid whose longer side (the base) contacts the piezoelectric material layer 101, is formed. Finally, an unnecessary portion is removed from the piezoelectric material layer 101 and the acoustic mirror layer 209 by etching (step p in FIG. 7B), thereby completing the piezoelectric resonator of FIG. 6B.

As described above, according to the piezoelectric resonator of the second embodiment of the present invention, an unwanted spurious signal is effectively suppressed, thereby making it possible to achieve a piezoelectric resonator having a high Q value. Particularly, by using the piezoelectric resonator manufacturing method of the present invention, a high-quality piezoelectric material layer can be applied to a resonator without impairing the crystallinity of the piezoelectric material layer. Electrical characteristics (admittance) of the piezoelectric resonator of the second embodiment are as described in the first embodiment.

Also in the second embodiment, the piezoelectric resonator can have various shapes, such as a rectangular shape, an elliptical shape, a polygonal shape, and the like (see FIGS. 5A to 5C). In addition, an oxide film, a nitride film, or an organic film may be provided at any positions for the purposes of insulation, temperature compensation, a deterioration in characteristics due to foreign matter, an improvement in resistance to humidity, and the like.

### Exemplary Configurations Employing the Piezoelectric Resonator

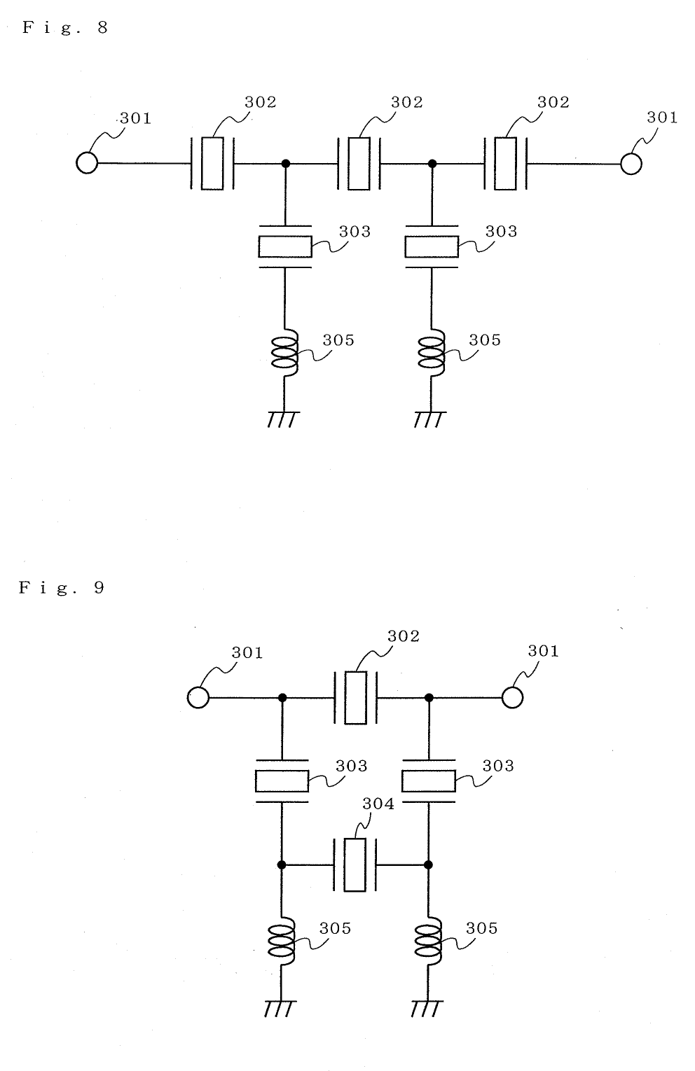

FIG. 8 is a diagram illustrating an exemplary piezoelectric filter circuit employing the piezoelectric resonator of the present invention. In the piezoelectric filter circuit of FIG. 8, serial piezoelectric resonators 302 inserted in series between I/O terminals 301 and parallel piezoelectric resonators 303 inserted in parallel therebetween are connected in a ladder form, and the parallel piezoelectric resonators 303 are grounded via inductors 305. By causing a resonant frequency of the serial piezoelectric resonator 302 and an anti-resonant frequency of the parallel piezoelectric resonator 303 to be substantially equal to each other, a band-pass radio frequency filter can be configured.

FIG. 9 is a diagram illustrating another exemplary piezoelectric filter circuit employing the piezoelectric resonator of the present invention. In the piezoelectric filter circuit of FIG. 9, serial piezoelectric resonators 302 and a bypass piezoelectric resonator 304 inserted in series between I/O terminals 301 and parallel piezoelectric resonators 303 inserted in parallel therebetween are connected in a lattice form, and the parallel piezoelectric resonators 303 are grounded via inductors 305. By causing a resonant frequency of the serial piezoelectric resonator 302 and an anti-resonant frequency of the parallel piezoelectric resonator 303 to be substantially equal to each other, and setting a resonant frequency of the bypass piezoelectric resonator 304 to be lower than the resonant frequency of the parallel piezoelectric resonator 303, a bandpass filter having a large out-of-band attenuation amount and low loss can be configured.

In such a piezoelectric filter circuit, spurious signals in the vicinity of the resonant frequency and the anti-resonant frequency of the piezoelectric resonator have a significant influence on characteristics in a pass band of the filter. By applying the piezoelectric resonator of the present invention which does not have a spurious signal in the pass band and has a high Q value, a radio frequency filter having low loss and excellent skirt characteristics can be obtained.

Note that the above-described configuration of the piezoelectric filter circuit employing the piezoelectric resonator of the present invention is only for illustrative purposes. The number of stages (the number of piezoelectric resonators) and the connection form are not limited to those described above. The present invention can be applied to various filters which utilize piezoelectric resonators, such as a lattice filter, a multi-mode filter in which a plurality of resonators are disposed adjacent to each other in a plane direction and in a thickness direction, and the like.

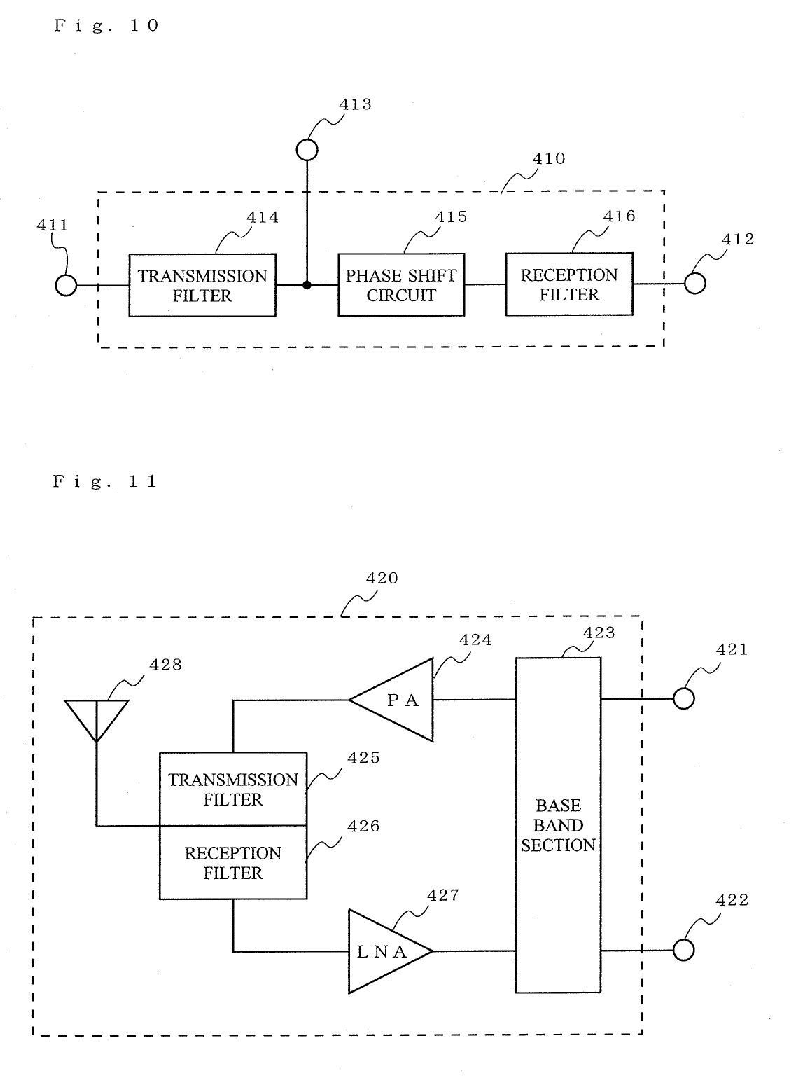

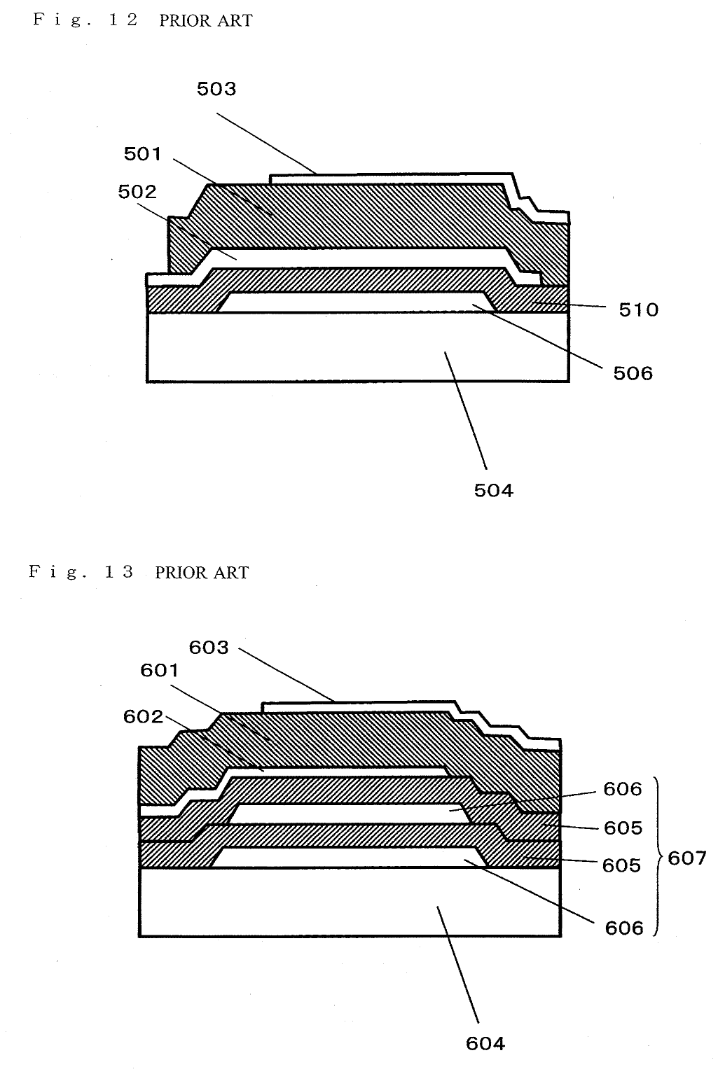

FIG. 10 is a diagram illustrating an exemplary duplexer 410 which employs the above-described piezoelectric filter circuit. In the duplexer 410 of FIG. 10, a transmission filter 414, a phase shift circuit 415, and a reception filter 416 are directly connected in sequence between a transmission terminal 411 and a reception terminal 412, and an antenna terminal 413 is connected between the transmission filter 414 and the phase shift circuit 415.

FIG. 11 is a diagram illustrating an exemplary communication apparatus 420 employing the above-described duplexer. In the communication apparatus 420 of FIG. 11, a signal input through a transmission terminal 421 is passed through a baseband section 423, is amplified in a power amplifier 424, is subjected to filtering in a transmission filter 425, and is transmitted as radio wave through an antenna 428. A signal received by the antenna 428 is subjected to filtering in a reception filter 426, is amplified in an LNA 427, is passed through the baseband section 423, and is transferred to a reception terminal 422.

While the invention has been described in detail, the foregoing description is in all aspects illustrative and not restrictive. It is understood that numerous other modifications and variations can be devised without departing from the scope of the invention.

1-4. (canceled)

5. A method for manufacturing a piezoelectric resonator, comprising the steps of:
forming a piezoelectric material layer on a first substrate;
forming a first electrode on one major surface of the piezoelectric material layer, the first electrode having a cross-section in the shape of a trapezoid whose longer side contacts the piezoelectric material layer;
transferring the piezoelectric material layer on which the first electrode is formed, from the first substrate to a second substrate using a wafer-to-wafer bonding method via a support portion; and
forming a second electrode on the other major surface of the piezoelectric material layer, the second electrode having a cross-section in the shape of a trapezoid whose longer side contacts the piezoelectric material layer.

6. The method according to claim 5, wherein the transferring step includes bonding the first and second substrates via a melted state or a half-melted state of the support portion made of a metal.

7. The method according to claim 5, wherein the transferring step includes bonding the first and second substrates by surface-activating and superposing the support portion made of an oxide thin film layer and the second substrate.

8-9. (canceled)
